(19) United States
(12) Patent Application Publication
(10) Pub. No.: US 2014/0182659 A1
(43) Pub. Date: Jul. 3, 2014

(54) METHODS FOR OPTIMIZING MATERIALS FOR LENSES AND LENS ARRAYS AND DEVICES THEREOF

(71) Applicants: Arthur J. Davis, Schaghticoke, NY (US); Juergen Zosel, Eckartsberga (DE); Steve Scott, Avon, CT (US)

(72) Inventors: Arthur J. Davis, Schaghticoke, NY (US); Juergen Zosel, Eckartsberga (DE); Steve Scott, Avon, CT (US)

(73) Assignee: ORAFOL AMERICAS INC., Avon, CT (US)

(21) Appl. No.: 14/124,366

(22) PCT Filed: Jun. 11, 2012
(86) PCT No.: PCT/US12/41922

§ 371 Date: Feb. 21, 2014

Related U.S. Application Data
(60) Provisional application No. 61/495,780, filed on Jun. 10, 2011.
(60) Provisional application No. 61/498,288, filed on Jun. 17, 2011.

(51) Int. Cl. H01L 31/052; G02B 3/08

(52) U.S. Cl. CPC H01L 31/0524; G02B 3/08
USPC 136/246; 359/742; 156/106

(57) ABSTRACT

This technology relates generally to methods for the fabrication of lenses which include a glass carrier and an at least partially transmissive layer with one or more slope facets coupled together by one or more draft facets on a surface of the glass carrier. This technology also relates to the resulting lenses and systems including lens arrays. These methods eliminate stress deformation in the resulting lenses by the use of a separator between the glass carrier and the at least partially transmissive layer, at least partial curing of the at least partially transmissive layer prior to formation of the slope and draft facets, modified at least partially transmissive layers which have a cure temperature at or below an operating temperature range of the lens, slope and draft facet dimensions which are selected to correspond with an operating temperature range of the lens, or UV-curable at least partially transmissive layers.

This application claims the benefit of U.S. Provisional Patent Application Ser. No. 61/495,780, filed Jun. 10, 2011, and U.S. Provisional Patent Application Ser. No. 61/498,288, filed Jun. 17, 2011, which are hereby incorporated by reference in their entirety.

### FIELD OF THE INVENTION

This technology relates generally to methods for the fabrication of lenses, and more particularly to the fabrication of silicone-on-glass Fresnel lenses. This technology also relates to the resulting lenses and lens arrays.

### BACKGROUND

Improving the efficiency of solar cells is critical for increased deployment which will result in the subsequent reduction of greenhouse gas emissions. This issue has become even more urgent as countries seek clean alternative energy sources. However, this must be accomplished at a competitive cost with respect to other energy sources. One solution gaining momentum is the branch of solar power known as concentrator photovoltaics (CPV) and concentrated solar power (CSP), where the cost reduction is derived from replacing inefficient photovoltaic (PV) cell material with lower cost optical systems. A typical concentrating photovoltaic (CPV) apparatus includes a lens array positioned to focus light from the sun onto a corresponding array of photovoltaic cells for the generation of electricity. Typically, the lens used to concentrate the solar light onto the photocell is a Fresnel lens comprising a superstrate or carrier and a Fresnel optical structure.

Silicone-on-glass (SOG) primary optics are one option for use in CPVs and in CSP arrays. In an SOG optic, the Fresnel lens is a hybrid made out of glass as a carrier and a silicone layer (or other flexible highly transmissive and UV stable polymers) with the Fresnel structure cast onto the underside or side toward the photocell. Thus, in these SOG primary optics, the glass carrier is exposed to the weather side while a micro structured Fresnel lens made of silicone is on the inside surface of the primary optic, where it is protected from exposure to the elements. These SOG CPVs or CSPs are useful in solar panels/modules, as they require only a very thin silicone layer and are very durable, exhibiting resistance to water, extreme temperatures, and other environmental factors.

The glass in the SOG structure typically has a coefficient of thermal expansion of 8-10 ppm/° C. which differs from the silicone which typically has a coefficient of thermal expansion in the range of 20-50 ppm/° C. As explained below, this difference can result in manufacturing problems.

The Fresnel lens is manufactured by thermally curing the silicone at an elevated temperature. At the cure temperature, the glass is larger in size than it is when at ambient temperature. When the Fresnel lens is brought back to ambient, the Fresnel structure in the silicone deviates from the shape of the mold due to the different rates of shrinkage of the glass and the silicone. The glass ends up with a low amount of tensile stress (due to by the strength of the material composition) and the silicone has a higher value of compressive stress which introduces deviations from the optical design values (some light curvature in the slopes). This change in dimension causes stress in facets of the Fresnel structure in the silicone which causes the facets to change shape and have a curved surface rather than the straight facet of the mold. This shape change causes the Fresnel lens performance to deviate from optimum, i.e., leading to losses in optical efficiency. This technology is directed to overcoming these and other deficiencies in the prior art.

### SUMMARY OF THE INVENTION

This technology relates to a lens comprising a glass carrier, an at least partially transmissive layer with one or more slope facets coupled together by one or more draft facets on a surface of the glass carrier, and a separator between the glass carrier and the at least partially transmissive layer.

This technology further relates to a method for making a lens. The method comprises providing a glass carrier, providing an at least partially transmissive layer with one or more slope facets coupled together by one or more draft facets on a surface of the glass carrier, and providing a separator between the glass carrier and the at least partially transmissive layer.

This technology also relates to a method for making a lens comprising providing a glass carrier, providing an at least partially transmissive layer which is at least partially cured on a surface of the glass carrier, and after the at least partial curing forming one or more slope facets coupled together by one or more draft facets on a surface of the at least partially transmissive layer.

This technology further relates to a lens comprising a glass carrier and an at least partially transmissive layer with one or more slope facets coupled together by one or more draft facets on a surface of the glass carrier, the at least partially transmissive layer comprising a modified layer which has a cure temperature which is at or below an operating temperature range of the lens.

This technology also relates to a method for making a lens comprising providing a glass carrier and providing an at least partially transmissive layer with one or more slope facets coupled together by one or more draft facets on a surface of the glass carrier, the at least partially transmissive layer comprising a modified layer which has a cure temperature which is at or below an operating temperature range of the lens.

Another aspect of this technology relates to a lens comprising a glass carrier, and an at least partially transmissive layer with one or more slope facets coupled together by one or more draft facets on a surface of the glass carrier, wherein the dimensions of the at least partially transmissive layer with one or more slope facets coupled together by one or more draft facets are selected to correspond with an operating temperature range for the lens.

This technology further relates to a method for making a lens comprising providing a glass carrier, and providing an at least partially transmissive layer with one or more slope facets coupled together by one or more draft facets on a surface of the glass carrier, wherein the dimensions of the at least partially transmissive layer are selected to correspond with an operating temperature range for the lens.

Another aspect of this technology relates to a lens comprising a glass carrier, and an at least partially transmissive layer with one or more slope facets coupled together by one or more draft facets on a surface of the glass carrier, wherein the at least partially transmissive layer is curable by ultraviolet light.

Yet another aspect of this technology relates to a method for making a lens, the method comprising providing a glass carrier, and providing an at least partially transmissive layer with one or more slope facets coupled together by one or more draft facets on a surface of the glass carrier which is curable by ultraviolet light.

A further aspect of this technology relates to a system including an array of lenses of any of the embodiments described herein and an array of photovoltaic cells configured with respect to the array of lenses to convert light energy passing through the array of lenses into electricity.

In a typical silicone-on-glass optic product, the slope and draft facets of the Fresnel lens are cast as valleys in the silicone nearly contacting the glass. The product is treated at elevated temperatures to cure the silicone; however, the final product at room temperature has a different dimensional shape from the theoretical shape or shape of the tool used to form the Fresnel lens due to stress deformation. The methods and devices described herein overcome this stress deformation of the facets of the lens.

### BRIEF DESCRIPTION OF THE DRAWINGS

FIG. 1 is a cross-sectional view of a lens in accordance with one embodiment of the present technology;

FIG. 2 is a cross-sectional view of a lens in accordance with another embodiment of the present technology;

FIG. 3 is a cross-sectional view of a lens in accordance with yet another embodiment of the present technology;

FIG. 4 is a graph showing the index of refraction at different temperatures for an exemplary silicone material in accordance with one embodiment of the present invention; and

FIG. 5 shows deformation of the slope of a prism facet of a Fresnel lens according to a spline profile in accordance with one embodiment of the present invention.

### DETAILED DESCRIPTION

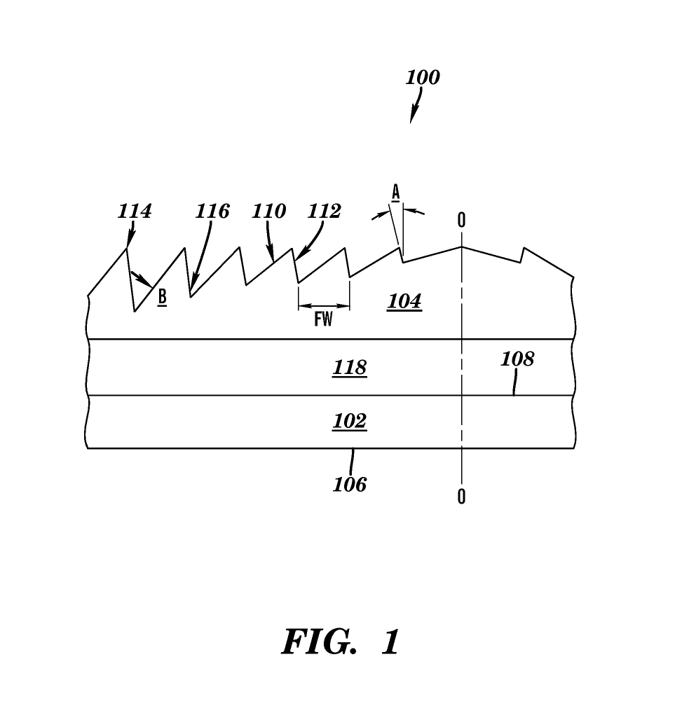

Referring to FIG. 1, a lens 100 in accordance with one embodiment of this technology is illustrated. The lens 100 includes a glass carrier 102 and an at least partially transmissive layer 104. The glass carrier 102 has a first surface 106 and a second surface 108. In one embodiment, the first surface 106 of the glass carrier 102 is exposed to the weather when used in a CPV.

In one exemplary embodiment, the glass carrier 102 has a thickness of from about 2.0 mm to about 6.0 mm. In another embodiment, the refractive index of the glass carrier is between about 1.515 and about 1.519. In a further embodiment, the glass carrier is a low iron float glass with less than about 0.4% iron content. In yet another embodiment, the glass carrier is partially heat strengthened per TVG DIN EN 1863, A2.

Referring to FIG. 1, the at least partially transmissive layer 104 is adjacent the second surface 108. As used herein, the term “at least partially transmissive” means a material which at least partially allows the transmission of light therethrough. In one embodiment, the at least partially transmissive layer 104 is highly transmissive allowing substantially all light from a particular light source to pass therethrough. The light source can be any suitable light source including, but not limited to, sunlight, lamplight, and artificial light. As used herein, the term “adjacent” means that the glass carrier and at least partially transmissive layer may or may not be in contact, but there is the absence of anything of the same kind in between.

In one exemplary embodiment, the at least partially transmissive layer is a silicone layer. Suitable at least partially transmissive layers include, but are not limited to, Dow Corning Sylgard 184 or equivalents, single component optically clear silicones, and optically clear pressure sensitive adhesives. In one exemplary embodiment, the at least partially transmissive layer 104 has a thickness of from about 0.1 mm to about 2.0 mm. In another embodiment, the refractive index of the at least partially transmissive layer 104 is between about 1.405 and about 1.420 when measured at the sodium D-line with 589 nanometer wavelength and 21° C.

The at least partially transmissive layer 104 includes one or more slope facets 110 coupled together by one or more draft (or relief) facets 112. The slope and draft facets 110, 112 form facet peaks 114 and facet valleys 116. Referring to FIG. 1, the facet angle B and draft angle A, as well as the facet width or pitch FW and optical axis O are shown. The particular dimensions of the slope and draft facets 110, 112 and the resulting facet angle, draft angle, and pitch are determined based on the intended use and properties of the lens. The angles of the facets typically are from zero or parallel to the surface up to a maximum of approximately 42 degrees from the surface. The height of the facets can be constant or variable and range typically from about 0.1 mm to about 1.0 mm based on the optical design. Typical pitch or facet spacing can be constant or variable and range from about 0.2 mm to about 0.9 mm.

In the embodiment shown in FIG. 1, the at least partially transmissive layer with one or more slope facets coupled together by one or more draft facets forms a Fresnel lens. In one embodiment, the facet angles of the Fresnel lens are designed such that a minimal spot diameter is achieved at a nominal focal length for one wavelength of light. Shorter and longer wavelengths will have a larger diameter at this nominal focal distance (having minimal spot diameters located above and below this nominal distance). Secondary optical elements (SOE) may be utilized to improve the concentration of the shorter and longer wavelengths of light. In another embodiment, the Fresnel lens includes a multi-focus approach. Multiple groove bands are used to focus a set of specific wavelengths. A set of adjacent facets may be associated with a specific set of wavelengths, with each prism shape crafted to focus an associated wavelength. This design method can direct light nominally to the photovoltaic cell location or to the SOE acceptance area in a CPV.

Referring to FIG. 1, a separator 118 is positioned between the glass carrier 102 and the at least partially transmissive layer 104. In the embodiment shown in FIG. 1, the separator 118 comprises a second at least partially transmissive material layer. By way of example only, the material between the glass and the first at least partially transmissive layer 104 could be a filled or unfilled adhesion layer, a nanoparticle-filled resin layer, a fast-cure resin layer, or other material that enhances performance of the Fresnel lens. In one exemplary embodiment, the second at least partially transmissive material layer has a thickness of from about 0.001 mm to about 0.6 mm. In another embodiment, the refractive index of the second at least partially transmissive material layer is between about 1.405 and about 1.420.

Suitable examples of adhesion layers are described, for example, in U.S. Pat. No. 5,755,866, which is hereby incorporated by reference in its entirety, and include, but are not limited to, OP2N-1 one part silicone primer from ACC Silicones. Suitable nanoparticle-filled resin layers are described, for example, in U.S. Patent Publication No. 2011/0240931 A1, which is hereby incorporated by reference in its entirety, and include, but are not limited to, resin layers with semiconductor nanoparticles, metal nanoparticles, and metal oxide nanoparticles. Suitable fast-cure resin layers are described, for example, in U.S. Pat. No. 3,996,187, which is hereby incorporated by reference in its entirety, and include, but are not limited to, Dow Corning PV8301. Examples of other materials include, but are not limited to, optically clear pressure sensitive adhesives, single part silicones, and silane based primer layers.

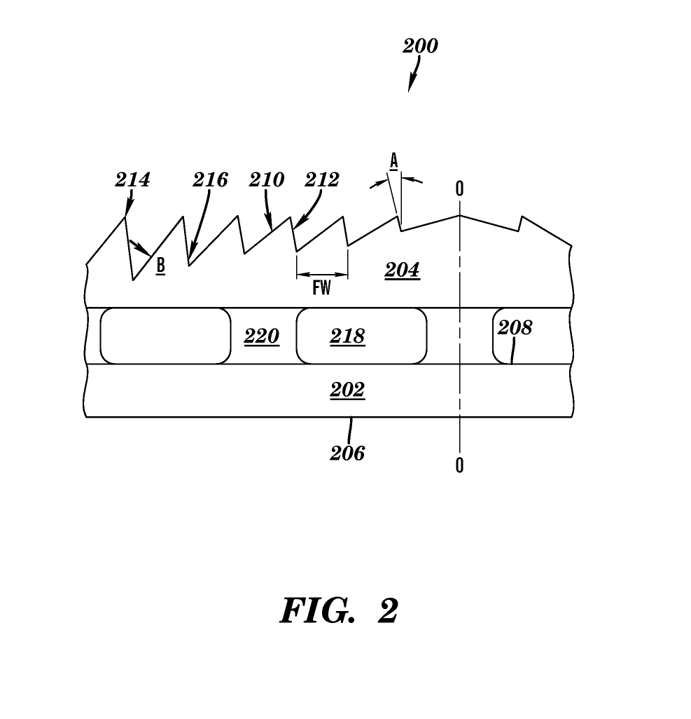

Referring to FIG. 2, another exemplary embodiment of a lens 200 is shown. As described above, the lens 200 includes a glass carrier 202 and an at least partially transmissive layer 204. The glass carrier 202 has a first surface 206 and a second surface 208. The at least partially transmissive layer 204 includes one or more slope facets 210 coupled together by one or more draft facets 212. The slope and draft facets 210, 212 form facet peaks 214 and facet valleys 216. The facet angle B and draft angle A, as well as the pitch FW and optical axis O are shown. As described above, the particular dimensions of the slope and draft facets 210, 212 and the resulting facet angle, draft angle and pitch are determined based on the intended use and properties of the lens. Suitable properties for the glass carrier and at least partially transmissive layer are described above with reference to FIG. 1.

In the embodiment shown in FIG. 2, the separator 218 comprises spacers of precast silicone or refractive index matched material. Suitable materials for the spacers include, but are not limited to, optical grade silicones cast to the required thickness and cut to act as spacers, index matched polymer shims, and pressure sensitive adhesives cut to the proper thickness and used as spacers. In one exemplary embodiment, the spacers have a thickness of from about 0.3 mm to about 0.8 mm. In another embodiment, the refractive index of the spacers is between about 1.400 and about 1.410. As shown in FIG. 2, the spacers 218 can be positioned in a layer 220, which is at least partially transmissive and can be the same or a different material than the at least partially transmissive layer 204. At least partially transmissive layer 204 and layer 220 can be cured separately or together.

The spacers can be installed on the mold for making the lens after applying the at least partially transmissive layer 204 and before applying the glass carrier 202. These spacers keep the glass carrier 202 from contacting the tool used to form the optical structure in the at least partially transmissive layer 204. In addition, by varying the pressure used in the casting process, a controlled thickness can be achieved with partially compressible or rigid spacers.

This technology also relates to a method for making a lens as shown, for example, in FIGS. 1-2. The method comprises providing a glass carrier, providing an at least partially transmissive layer with one or more slope facets coupled together by one or more draft facets on a surface of the glass carrier, and providing a separator between the glass carrier and the at least partially transmissive layer. This exemplary method separates the groove structure in the at least partially transmissive layer from the glass carrier with a separator to isolate the stresses caused by the thermal coefficient of expansion mismatch described above, although other manners for compensating for the thermal coefficient of expansion mismatch could be used as described below.

In accordance with this method, the separator can be precast on the glass to separate the at least partially transmissive layer from the glass.

Suitable glass carriers, at least partially transmissive layers, and separators are described above with reference to FIGS. 1-2.

This technology further relates to a method for making a lens comprising providing a glass carrier, providing an at least partially transmissive layer which is at least partially cured on a surface of the glass carrier, and after the at least partial curing forming one or more slope facets coupled together by one or more draft facets on a surface of the at least partially transmissive layer.

Suitable at least partially transmissive layers include, but are not limited to, silicones (e.g., optical grade silicones cast to the required thickness), optically clear pressure sensitive adhesive layers, and UV curable acrylates cast to the proper thickness.

In accordance with one embodiment, the at least partially transmissive layer is cured to a state where at least the surface has enough cure to not flow so that the facet structure can be formed on the partially cured material. In accordance with another embodiment, the at least partially transmissive layer is substantially cured prior to forming the one or more slope facets coupled together by one or more draft facets. The particular cure time and conditions are determined based on material used for the at least partially transmissive layer and the intended properties of the lens. For example, the at least partially transmissive layer can be cured by chemical additives, ultraviolet radiation, electron beam, or heat, as known to one of ordinary skill in the art.

Techniques for forming one or more slope facets coupled together by one or more draft facets on a surface of the at least partially transmissive layer are known in the art and are described, for example, in U.S. Pat. No. 4,170,616, which is hereby incorporated by reference in its entirety. Suitable techniques include coating a tool with a layer of at least partially transmissive material and then impressing a nickel tool having the desired design into the at least partially transmissive material layer and completing curing.

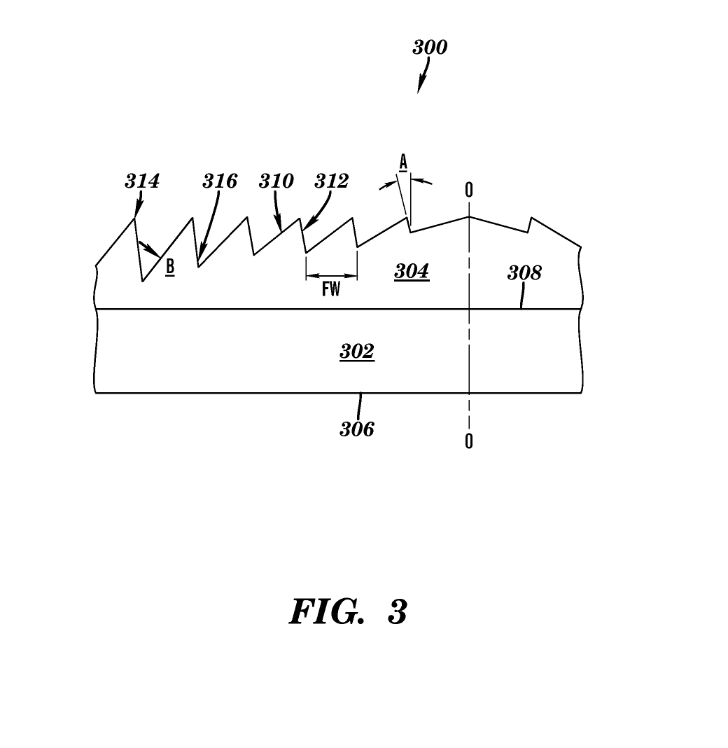

Referring to FIG. 3, a lens 300 in accordance with one embodiment of this technology is illustrated. The lens 300 includes a glass carrier 302 and an at least partially transmissive layer 304. The glass carrier 302 has a first surface 306 and a second surface 308. In one embodiment, the first surface 306 of the glass carrier 302 is exposed to the weather when used in a CPV.

Suitable properties for the glass carrier are described above.

Referring to FIG. 3, in this embodiment, the at least partially transmissive layer 304 is adjacent and in contact with the second surface 308. In one exemplary embodiment, the at least partially transmissive layer is a silicone layer, although other suitable at least partially transmissive layers can be used as described herein.

As shown in FIG. 3, the at least partially transmissive layer 304 includes one or more slope facets 310 coupled together by one or more draft facets 312. The slope and draft facets 310, 312 form facet peaks 314 and facet valleys 316. The facet angle B and draft angle A, as well as the pitch FW and optical axis O are also shown. As described above, the particular dimensions of the slope and draft facets 310, 312 and the resulting facet angle, draft angle and pitch are determined based on the intended use and properties of the lens.

In the embodiment shown in FIG. 3, the at least partially transmissive layer 304 is a modified layer which has a cure temperature which is at or below an operating temperature range of the lens. In one embodiment, the modified layer is a customized silicone which cures faster at a lower temperature. Such customized silicones can be created based on the desired cure temperature and rate and are available, for example, as Loctite 5033 Nuva-Sil Silicone.

This technology also relates to a method for making a lens. This method involves providing a glass carrier and providing an at least partially transmissive layer with one or more slope facets coupled together by one or more draft facets on a surface of the glass carrier, the at least partially transmissive layer comprising a modified layer which has a cure temperature which is at or below an operating temperature range of the lens. As described above, in this method for making a lens, customized at least partially transmissive layers which cure faster at lower temperatures are used and the production curing temperatures are identical or nearly identical to the operation temperature of the lens. This exemplary method compensates for the thermal coefficient of expansion mismatch between the glass carrier and the at least partially transmissive layer by eliminating the need to cure the at least partially transmissive layer at temperatures which cause changes in dimension due to the different rates of shrinkage of the glass and the at least partially transmissive layer.

Another aspect of this technology relates to a lens comprising a glass carrier, and an at least partially transmissive layer with one or more slope facets coupled together by one or more draft facets on a surface of the glass carrier, wherein the dimensions of the at least partially transmissive layer with one or more slope facets coupled together by one or more draft facets are selected to correspond with an operating temperature range for the lens.

In this embodiment, the design and dimensions of the slope and draft facets and the resulting facet angle, draft angle, and pitch of the at least partially transmissive layer are modified based on the intended operating temperature for the lens. In one embodiment, the design and dimensions are modified so that the optical structure in the at least partially transmissive layer can deviate from the shape of the mold when shrinking after cure to a desired shape and dimensions for use within an operating temperature range for the lens. This optimizes the performance of the resulting lens at different climate zones. Thus, with this technology, stress deformation of the prism facets of the lens, e.g., Fresnel lens, also can be considered in the design process by direct modeling.

In another embodiment, the temperature dependence of the index of refraction of the at least partially transmissive layer is used to design an optical structure in the at least partially transmissive layer to perform optimally for different operating temperatures. For example, knowing that the lens is to be predominately used in temperatures above 35° C., the design of the one or more slope facets coupled together by one or more draft facets can be compensated to ensure that the optical structure focuses optimally at this temperature by designing it to use the index of refraction of at least partially transmissive layer at this temperature.

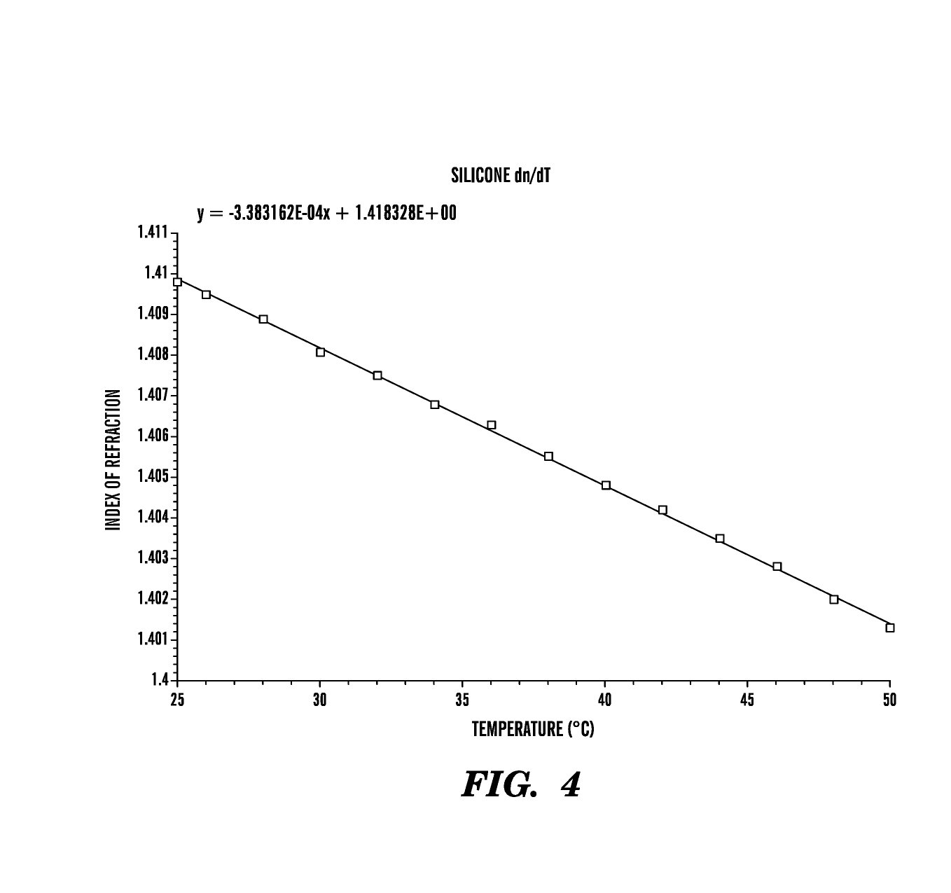

Different curing temperatures or different at least partially transmissive materials could be used for different locations depending on the average outside temperature in that location. A graph of the index of refraction at different temperatures for an exemplary silicone material for the at least partially transmissive material is illustrated in FIG. 4.

Another aspect of this technology relates to a method for making a lens comprising providing a glass carrier, and providing an at least partially transmissive layer with one or more slope facets coupled together by one or more draft facets on a surface of the glass carrier, wherein the dimensions of the at least partially transmissive layer with one or more slope facets coupled together by one or more draft facets are selected to correspond with an operating temperature range for the lens.

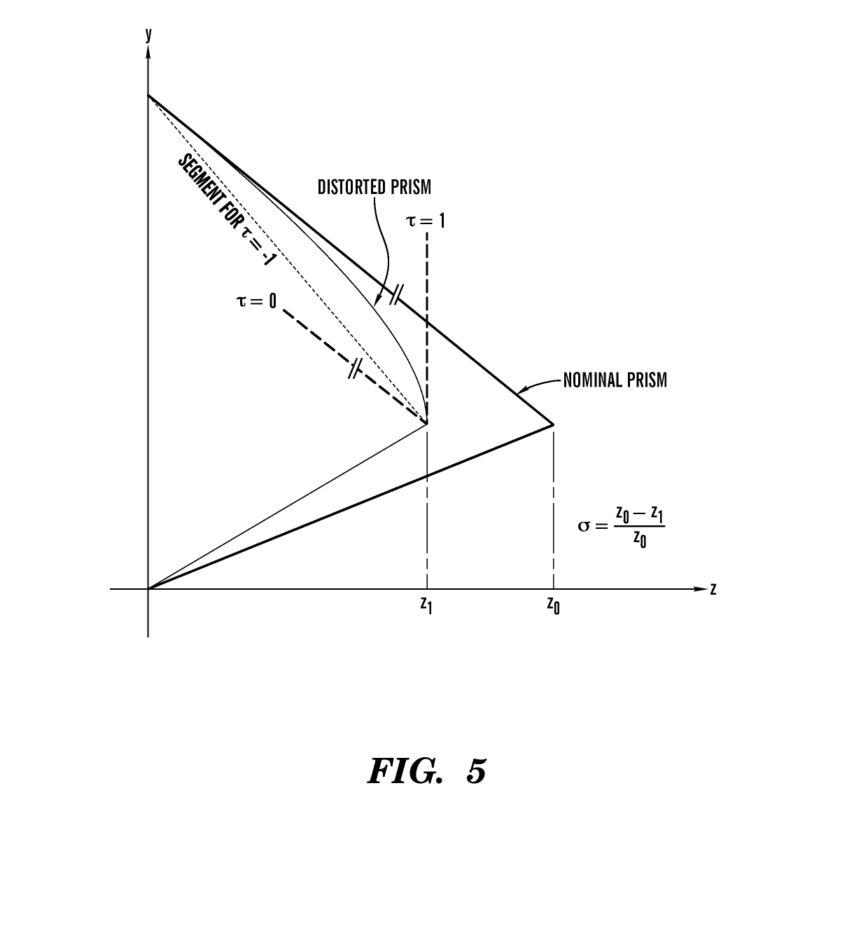

An exemplary method has been developed which deforms the slope of the prism facet according to a spline profile and is illustrated in FIG. 5. In particular, the correction is defined as a spline profile and subtracted from the theoretical slope profile. The resultant is then used to form the slope surface. As described above, by deforming the slope of the prism facet, the optical structure in the at least partially transmissive layer can deviate from the shape of the mold when shrinking after cure to a desired shape and dimensions for use within an operating temperature range for the lens.

Another aspect of this technology relates to a lens comprising a glass carrier, and an at least partially transmissive layer with one or more slope facets coupled together by one or more draft facets on a surface of the glass carrier, wherein the at least partially transmissive layer is curable by ultraviolet light. Suitable ultraviolet light sources include metal-halide lamps, LEDs, eximer lasers, and other types of UV lamps.

Yet another aspect of this technology relates to a method for making a lens, the method comprising providing a glass carrier, and providing an at least partially transmissive layer with one or more slope facets coupled together by one or more draft facets on a surface of the glass carrier which is curable by ultraviolet light.

Suitable properties for the glass carrier are described above.

In one exemplary embodiment, the at least partially transmissive layer has a thickness of from about 0.2 mm to about 0.9 mm. In another embodiment, the refractive index of the at least partially transmissive layer is between about 1.400 and about 1.410

Suitable materials for the at least partially transmissive layer which is curable by ultraviolet light include, but are not limited to, a UV-curable silicone or a UV-curable acrylate, such as Novargard UV optically clear silicone. UV-curable silicones may be one or two part systems that use UV radiation to initiate the curing process. As described above, the particular dimensions of the slope and draft facets and the resulting facet angle, draft angle and pitch are determined based on the intended use and properties of the lens.

In accordance with these embodiments, an at least partially transmissive layer that is cured by UV is used to overcome the temperature issues of catalyst-cured silicones.

A further aspect of this technology relates to a system including an array of lenses of any of the embodiments described above and an array of photovoltaic cells configured with respect to the array of lenses to convert light energy passing through the array of lenses into electricity.

Having thus described the basic concept of the invention, it will be rather apparent to those skilled in the art that the foregoing detailed disclosure is intended to be presented by way of example only, and is not limiting. Various alterations, improvements, and modifications will occur and are intended to those skilled in the art, though not expressly stated herein. These alterations, improvements, and modifications are intended to be suggested hereby, and are within the spirit and scope of the invention. Additionally, the recited order of processing elements or sequences, or the use of numbers, letters, or other designations therefore, is not intended to limit the claimed processes to any order except as may be specified in the claims. Accordingly, the invention is limited only by the following claims and equivalents thereto.

What is claimed is:

1. A lens comprising:
a glass carrier;
a first at least partially transmissive layer with one or more slope facets coupled together by one or more draft facets on a surface of the glass carrier; and
a separator between the glass carrier and the first at least partially transmissive layer.

2. The lens according to claim 1, wherein the first at least partially transmissive layer is a silicone layer.

3. The lens according to claim 1, wherein the first at least partially transmissive layer with one or more slope facets coupled together by one or more draft facets forms a Fresnel optical structure.

4. The lens according to claim 1, wherein the separator comprises a second at least partially transmissive layer.

5. The lens according to claim 4, wherein the second at least partially transmissive layer comprises one of an adhesion layer, a nanoparticle-filled resin layer, and a fast-cure resin layer.

6. The lens according to claim 1, wherein the separator comprises one or more spacers.

7. The lens according to claim 6, wherein the one or more spacers comprise precast silicone or a refractive index matched material.

8. A system comprising:
an array of lenses according to claim 1, and
an array of photovoltaic cells configured with respect to the array of lenses to convert light energy passing through the array of lenses into electricity.

9. A method for making a lens, the method comprising:
providing a glass carrier;
providing a first at least partially transmissive layer with one or more slope facets coupled together by one or more draft facets on a surface of the glass carrier; and
providing a separator between the glass carrier and the first at least partially transmissive layer.

10. The method according to claim 9, wherein the first at least partially transmissive layer is a silicone layer.

11. The method according to claim 9, wherein the first at least partially transmissive layer with one or more slope facets coupled together by one or more draft facets forms a Fresnel optical structure.

12. The method according to claim 9, wherein providing the separator comprises providing a second at least partially transmissive layer on a surface of the glass carrier before the providing of the first at least partially transmissive layer with the one or more slope facets coupled together by one or more draft facets.

13. The method according to claim 12, wherein the second at least partially transmissive layer comprises one of an adhesion layer, a nanoparticle-filled resin layer, and a fast-cure resin layer.

14. The method according to claim 9, wherein providing the separator comprises positioning one or more spacers on the at least partially transmissive layer.

15. The method according to claim 14, wherein the one or more spacers comprise precast silicone or a refractive index matched material.

16. A method for making a lens, the method comprising:
providing a glass carrier;
providing an at least partially transmissive layer which is at least partially cured on a surface of the glass carrier; and
after the at least partial curing, forming one or more slope facets coupled together by one or more draft facets on a surface of the at least partially transmissive layer.

17. The method according to claim 16, wherein the at least partially transmissive layer is a silicone, an optically clear pressure sensitive adhesive layer, or a UV-curable acrylate.

18. The method according to claim 16, wherein the at least partially transmissive layer is substantially cured prior to the forming.

19. The method according to claim 16, wherein the at least partially transmissive layer with one or more slope facets coupled together by one or more draft facets forms a Fresnel optical structure.

20. A lens comprising:
a glass carrier; and
an at least partially transmissive layer with one or more slope facets coupled together by one or more draft facets on a surface of the glass carrier, the at least partially transmissive layer comprising a modified layer which has a cure temperature which is at or below an operating temperature range of the lens.

21. The lens according to claim 20, wherein the at least partially transmissive layer is a silicone layer.

22. The lens according to claim 20, wherein the at least partially transmissive layer with one or more slope facets coupled together by one or more draft facets forms a Fresnel optical structure.

23. A system comprising:
an array of lenses according to claim 20, and
an array of photovoltaic cells configured with respect to the array of lenses to convert light energy passing through the array of lenses into electricity.

24. A method for making a lens, the method comprising:
providing a glass carrier; and
providing an at least partially transmissive layer with one or more slope facets coupled together by one or more draft facets on a surface of the glass carrier, wherein the at least partially transmissive layer comprises a modified layer which has a cure temperature which is at or below an operating temperature range of the lens.

25. The method according to claim 24, wherein the at least partially transmissive layer is a silicone layer.

26. The method according to claim 24, wherein the at least partially transmissive layer with one or more slope facets coupled together by one or more draft facets forms a Fresnel optical structure.

27. A lens comprising:
a glass carrier; and
an at least partially transmissive layer with one or more slope facets coupled together by one or more draft facets on a surface of the glass carrier, wherein the dimensions of the at least partially transmissive layer with one or more slope facets coupled together by one or more draft facets are selected to correspond with an operating temperature range for the lens.

28. The lens according to claim 27, wherein the at least partially transmissive layer is a silicone layer.

29. The lens according to claim 27, wherein the at least partially transmissive layer with one or more slope facets coupled together by one or more draft facets forms a Fresnel optical structure.

30. A system comprising:
an array of lenses according to claim 27, and
an array of photovoltaic cells configured with respect to the array of lenses to convert light energy passing through the array of lenses into electricity.

31. A method for making a lens, the method comprising:
providing a glass carrier; and
providing an at least partially transmissive layer with one or more slope facets coupled together by one or more draft facets on a surface of the glass carrier, wherein the dimensions of the at least partially transmissive layer with one or more slope facets coupled together by one or more draft facets are selected to correspond with an operating temperature range for the lens.

32. The method according to claim 31, wherein the at least partially transmissive layer is a silicone layer.

33. The method according to claim 31, wherein the at least partially transmissive layer with one or more slope facets coupled together by one or more draft facets forms a Fresnel optical structure.

34. The method according to claim 31, wherein selecting the dimensions to correspond with an operating temperature comprises deforming the slope of the one or more slope facets according to a spline profile.

35. The method according to claim 31, wherein selecting the dimensions to correspond with an operating temperature comprises formulating the dimensions of the one or more slope facets and the one or more draft facets to use the index of refraction of the at least partially transmissive layer at the operating temperature range.

36. A lens comprising:
a glass carrier; and
an at least partially transmissive layer with one or more slope facets coupled together by one or more draft facets on a surface of the glass carrier, wherein the at least partially transmissive layer is curable by ultraviolet light.

37. The lens according to claim 36, wherein the at least partially transmissive layer is a UV-curable silicone or a UV-curable acrylate.

38. A system comprising:
an array of lenses according to claim 36, and
an array of photovoltaic cells configured with respect to the array of lenses to convert light energy passing through the array of lenses into electricity.

39. A method for making a lens, the method comprising:
providing a glass carrier; and
providing an at least partially transmissive layer with one or more slope facets coupled together by one or more draft facets on a surface of the glass carrier, wherein the at least partially transmissive layer is cured by ultraviolet light.

40. The method according to claim 39, wherein the at least partially transmissive layer is a UV-curable silicone or a UV-curable acrylate.
